(19) United States
(12) Patent Application Publication
(10) Pub. No.: US 2007/0210030 A1
(43) Pub. Date: Sep. 13, 2007

(54) Method of patterning conductive structure

(76) Inventor: Been-Jon Woo, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 11/373,138

(22) Filed: Mar. 13, 2006

(51) Int. Cl. C23F 1/00; C03C 25/68; H01L 21/302

(52) U.S. Cl. 216/41; 216/58; 216/79; 438/717; 438/719

(57) ABSTRACT

A method of patterning a conductive structure includes providing a semiconductor substrate, forming a conductive layer on the semiconductor substrate, forming a hard mask layer on the conductive layer and forming a photo-resist layer on the hard mask layer. An isotropic etching is applied to remove a partial region of the photo-resistant layer in order to form a patterned photo-resistant layer. Then, the patterned photo-resistant layer is used as a mask to form a patterned hard mask layer by etching the hard mask layer. Next, the patterned hard mask layer is used as another mask to remove the partial region of the conductive layer to form a patterned conductive layer. The patterned photo-resist layer is only used for etching the hard mask layer, therefore it is able to enhance the resolution when using a thinner photo-resistant layer, furthermore to fabricate a patterned conductive layer with a miniaturized dimensional structure.

### FIELD OF THE INVENTION

1. Field of the Invention

The present invention relates to a method of patterning a conductive structure, especially as it relates to a patterning method of a hard mask layer applied to a photo-resist layer.

2. Description of the Related Art

Photolithography technology is one of most pivotal steps in the semiconductor manufacturing process. The complexity of the process is determined by frequencies of the photolithography, or the amount of photo mask required. In addition, the densities of ICs components can be high density to form the smaller pattern-width, which also depends on the success of photolithography manufacturing processes.

The basic principle of the photolithography is taking a specific incident wavelength light and transferring the photo mask pattern to the photo-resist on the semiconductor substrate. Then by applying the exposure and etching procedure, the desired components of semiconductor are obtained. The quality of the photo-resist is related to photosensitivity, superior adhesion, anti-etching and resolution of the photo-resist, and so on. Generally, inferior coherence and anti-etching cause errors or failures when patterning is underway. Therefore, the quality of the photo-resist is dependent on the accuracy and precision of the manufacturing process.

In general, the thinner the photo-resist, the better the resolution. But from the point of avoiding impunity, it is better to use a thicker photo-resist for avoiding anti-etching effect, for example, when patterning of poly-silicon is under way, it needs a thicker photo-resist for avoiding etch-out effect. Consequently, it reduces the resolution and is unfavorable to form a smaller size semiconductor component.

### SUMMARY OF THE INVENTION

In view of the above, in order to reduce the thickness of the photo-resist, the present invention is to provide a method of patterning a conductive structure, and applying a hard mask layer to carry out patterning for photo-resist layer.

In order to form a semiconductor component with a miniaturized structural dimension, the present invention is to provide a patterning method for a gate electrodes, which takes advantage of the photo-resist layer and hard mask layer to miniaturize the ICs size.

In order to reach above goals, the invention presented here proposes a method of patterning for conductive structures. In the first step, it is provides a semiconductor substrate, wherein a conductive layer forms on the semiconductor substrate. A hard mask layer then forms on the conductive layer and forms a photo-resist layer over the hard mask layer. The second step involves applying isotropic etching to remove partial region of the photo-resistant layer in order to form a patterned photo-resistant layer. The patterned photo-resistant layer is used as a mask to form a patterned hard mask layer by etching the hard mask layer. After that, the patterned hard mask layer is used as a mask to remove a partial region of the conductive layer to form a patterned conductive layer. The patterned photo-resist layer is only used for etching the hard mask layer, therefore it is able to enhance the resolution when using a thinner photo-resistant layer, furthermore forming a patterned conductive layer with a smaller dimensional structure.

Hereinafter, embodiments of the invention are discussed below with reference to the Figures.

### BRIEF DESCRIPTION OF THE DRAWINGS

FIG. 1A to FIG. 1C are sectional schematic diagrams for a semiconductor component according to the present invention.

### DETAILED DESCRIPTION OF THE PREFERRED EMBODIMENTS

This method was chosen and described in order to demonstrate its utilization in many practical applications. Those skilled in the art will appreciate that with various modifications, substitution is possible, without departing from the scope of the invention.

Next, the preferred method of the present invention will now be described with reference to the attached schematic diagrams. Please note the cross-sectional and vertical views of the semiconductor structure are not in proportional to the actual object. But for illustrating purposes, however, we will use these diagrams to describe the method. Additionally, the actual manufacturing should contain the length, width and the depth of three-dimensional space size.

Therefore, the present invention proposes a patterning method for a gate electrode. In the first step, a semiconductor substrate has a poly silicon layer formed thereon. A hard mask layer forms on the poly silicon layer and then a photo-resist layer forms on the hard mask layer. A second step involves applying isotropic etching to remove partial photo-resist layer to expose partial hard mask layer, and then to remove partially exposed hard mask layer to expose partial poly silicon layer. A further step involves removing patterned photo-resist layer, and then removing partially exposed poly silicon layer to form a patterned poly silicon layer. Finally, the patterned hard mask layer is removed.

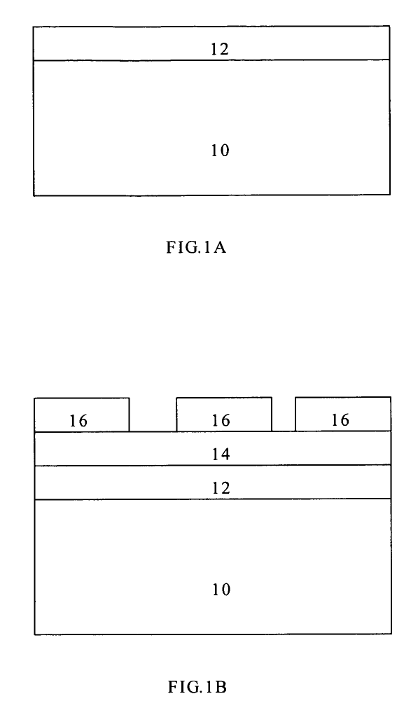

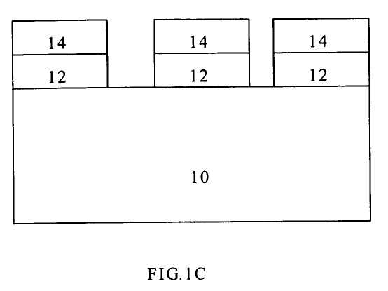

The cross-sectional views of the semiconductor component disclosed herein are shown in FIG. 1A and FIG. 1C according to the present invention. As shown in FIG. 1A, a semiconductor structure 10 includes the required fabricated semiconductor structure, (not shown in diagram), such as a silicon-substrate, a substrate with N-type or P-type well or both, and a isolation component with a field-oxygen region forming by the region-oxidation method or a shallow trench isolation component fabricated by locality oxidation. Moreover, the present invention also has an application which applies to other multi-layer structures, therefore, the semiconductor structure 10 which itself can also have a multi-layer structure, is not limited by this embodiment. And then, it uses a commonly suitable way to form a conductive layer 12 on the semiconductor structure 10. In this embodiment, the conductive layer 12 is a poly silicon layer, it is provided to act as a gate electrode, therefore, there is a gate-oxidation layer (not shown in diagram) between the semiconductor 10 and conductive layer 12. Moreover, the material of the present invention is not confined in a poly silicon layer 12 formed as the conductive layer, and the conductive layer is not only formed as a gate electrode. Both semiconductor component and structure fabricated by photolithography are considered within the sprit and scope of the claimed invention.

Referring to FIG. 1B, for one of characteristics of this invention, there is a hard mask layer 14 and a photo-resist layer 16 fabricated on the conductive layer 12. In this embodiment, the hard mask layer 14 is an oxynitride layer with a width approximately 200 angstroms. Due to the applied hard mask layer 14 is used as an etching mask for etching the conductive layer 12, therefore, if any material which relates to conductive layer 12 has a good etching-selective ratio, which can be use as hard mask layer 14 for this invention, it is not confined in oxynitride layer. Then, it uses an exposure light source with 248 nm of wavelength, continuously applying patterning, exposure, isotropic etch back processes, and so on, then fabricates a patterned photo-resist layer 16. One of characteristics of the present invention is that the photo-resist layer 16 is only used as for etching the hard mask layer 14, therefore, thinner photo-resist layer 16 can be used to provide better resolution.

Afterwards, referring to FIG. 1C, the patterned photo-layer 16 is used as an etching mask to remove partial of the hard mask layer 14, just like removing part of patterned photo-layer 16 which exposes the hard mask layer 14, then removing the photo-resist layer 16 to form a patterned hard mask 14. After that, it is used the patterned hard mask 14 as an etching mask, not used the photo-resist layer 16 as the etching mask, to remove part of the conductive layer 12, therefore gratefully reduces the thickness of the photo-resist layer 16, and also obtains a smaller patterned conductive layer 12 to form a 100 submicron of gate electrode. One of purpose of this invention, owing to apply hard mask layer as an etching mask, when it is removed residual conductive layer and a washing process is carried out, it is impossible to form a high-polymer residue on the substrate surface.

The above described embodiments are for explaining technical concepts and features. Those skilled in the art will appreciate that with various modifications, substitution is possible, without departing from the scope of the inventions as disclosed in the accompanying claims.

What is claimed is:

1. A patterning method of a conductive structure, which comprises the steps of:
providing a semiconductor substrate where a conductive layer forms on the semiconductor substrate;
forming a hard mask layer on the conductive layer;
forming a photo-resist layer on the hard mask layer;
applying isotropic etching to remove a partial region of the photo-resist layer to form a patterned photo-resist layer;
using the patterned photo-resist layer as a first mask to form a patterned hard mask by etching the hard mask layer;
using the patterned hard mask layer as a second mask to remove a partial region of the conductive layer to form the patterned conductive layer.

2. The patterning method according to claim 1, further including the step of removing the patterned photo-resist layer after forming the patterned hard mask layer and before removing the partial region of the conductive layer.

3. The patterning method according to claim 1, further including the step of removing the patterned photo-resist layer and the patterned hard mask layer after forming the patterned conductive layer.

4. The patterning according to claim 1, further including forming an isolation layer between the semiconductor substrate and the conductive layer.

5. The patterning method according to claim 1, wherein the conductive layer is a poly silicon layer deposited on the semiconductor substrate.

6. The patterning method according to claim 5, wherein the hard mask layer is formed as an oxynitride layer

7. A patterning method for a gate-electrode, which comprises the step of:
providing a semiconductor substrate where a poly silicon layer forms on the semiconductor substrate;
forming a hard mask layer on the poly silicon layer;
forming a photo-resist layer on the hard mask layer;
applying isotropic etching to remove a partial region of the photo-resist layer to formed a patterned photo-resist layer and exposing a partial region of the hard mask layer;
removing the exposed hard mask layer to form a patterned hard mask layer and exposing a partial region of the poly silicon layer;
removing the patterned photo-resist layer;
removing the exposed poly silicon layer to form a patterned poly silicon layer; and
removing the patterned hard mask layer.

8. The patterning method according to claim 7, wherein the hard mask layer is a oxynitride layer.

9. The patterning method according to claim 7, further including exposing the photo-resist layer to a light with 248 nm in wavelength.
